(19) United States
(12) Patent Application Publication
(10) Pub. No.: US 2026/0198182 A1
(43) Pub. Date: Jul. 9, 2026

(54) Display Substrate and Display Device

(71) Applicants: Chengdu BOE Optoelectronics Technology Co., Ltd., Chengdu, Sichuan (CN); BOE Technology Group Co., Ltd., Beijing (CN)

(72) Inventors: Yu Wang, Beijing (CN); Wei Zhang, Beijing (CN); Xiangdan Dong, Beijing (CN); Hongli Wang, Beijing (CN); Jun Yan, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/839,489

(22) PCT Filed: Sep. 28, 2023
(86) PCT No.: PCT/CN2023/122378

§ 371 Date: Aug. 19, 2024

(51) Int. Cl. H10K 59/122

(52) U.S. Cl. CPC H10K 59/122

(57) ABSTRACT

A display substrate and a display device are provided. The display substrate includes a conductive structure and an inorganic layer. The display substrate includes a first region and a second region; the conductive structure and the inorganic layer are located in the first region and the second region. The first region includes a display region, the second region includes a non-display region, the display region includes sub-pixels and a definition structure; the sub-pixel includes a light-emitting functional layer, the definition structure includes a portion of the inorganic layer located in the display region, and a portion of the definition structure located between adjacent sub-pixels is configured to isolate the light-emitting functional layer; in the second region, the inorganic layer includes a sub-portion exposing at least a portion of the conductive structure and/or includes a sub-portion in contact with the conductive structure.

### TECHNICAL FIELD

Embodiments of the present disclosure relate to a display substrate and a display device.

### BACKGROUND

With the development of display technology, users have more and more demands on the performance of display devices. Organic light-emitting diode (OLED) display products are more and more popular because of being colorful, having fast response time, being foldable and other advantages. The organic light-emitting diode display device includes a tandem device. The performance requirements of high brightness and low power consumption of the display device may be satisfied as much as possible by isolating the material layer for light emission between adjacent sub-pixels to reduce signal crosstalk.

### SUMMARY

The present disclosure provides a display substrate and a display device.

The present disclosure provides a display substrate, which includes: a base substrate and a conductive structure and an inorganic layer on the base substrate. The base substrate includes a first region and a second region; the conductive structure is located in the first region and the second region on the base substrate; and the inorganic layer is located on a side of the conductive structure away from the base substrate and located in the first region and the second region. The first region includes a display region, the second region includes a portion of a non-display region, the display region includes a plurality of sub-pixels and a definition structure; each sub-pixel in at least a portion of the sub-pixels includes a light-emitting functional layer, the light-emitting functional layer includes a plurality of film layers; the definition structure includes a portion of the inorganic layer located in the display region, the definition structure is located between the light-emitting functional layer and the base substrate, and a portion of the definition structure located between adjacent sub-pixels is configured to isolate at least one layer of the light-emitting functional layer; in the second region, the inorganic layer includes a sub-portion exposing at least a portion of the conductive structure and/or the inorganic layer includes a sub-portion in contact with the conductive structure.

For example, the display substrate further includes: an organic layer located between a film layer where the inorganic layer is located and the base substrate. The definition structure further includes at least one protrusion in the organic layer in contact with a surface of the inorganic layer, at least a portion of an edge of the protrusion is retracted inward respect to an edge of the inorganic layer in the definition structure.

For example, in a direction perpendicular to the base substrate, a portion of the conductive structure located in at least a portion of the second region does not overlap with the organic layer.

For example, in at least a portion of the second region, the organic layer covers an edge of the conductive structure, and the inorganic layer covers an edge of the organic layer and exposes at least a portion of the conductive structure.

For example, the second region includes a first sub-region in which the inorganic layer covers the conductive structure and is in contact with a surface of the conductive structure.

For example, a portion of the conductive structure located in the first sub-region includes a test pad.

For example, the second region further includes a second sub-region in which the inorganic layer covers an edge of the conductive structure.

For example, the portion of the conductive structure located in the second sub-region includes a contact pad configured to electrically connect with a pin of a circuit board.

For example, in a direction perpendicular to the base substrate, at least a portion of the organic layer located in the second region is removed.

For example, each sub-pixel of the at least some sub-pixels further includes a first electrode and a second electrode located at both sides of the light-emitting functional layer, the first electrode being located between the light-emitting functional layer and the base substrate; the display substrate further includes a pixel definition pattern, the pixel definition pattern includes a plurality of first openings and a plurality of second openings; one sub-pixel corresponds to at least one first opening, at least a portion of the light-emitting functional layer of the sub-pixel is located in the first opening corresponding to the sub-pixel, the first opening is configured for exposing the first electrode, and the second opening is configured for exposing an edge of the definition structure.

For example, the first sub-region is located between the second sub-region and the first region.

For example, a portion of the conductive structure located at the second region includes a power supply signal line, and the inorganic layer is in contact with part of a surface of the power supply signal line.

For example, the display substrate further includes: at least one ring of barriers surrounding the display region, wherein at least a portion of a film layer of the barriers is located on a side of the conductive structure away from the base substrate. An orthographic projection of the power supply signal line on the base substrate overlaps with an orthographic projection of the at least one ring of barriers on the base substrate; a portion of the power supply signal line located at the second region extends in a first direction, a portion of the at least one ring of barriers located at the second region includes a strip-shaped barrier extending in a second direction, and at least a portion of the inorganic layer located at the second region extends in the second direction, the first direction intersects with the second direction.

For example, at least a portion of the inorganic layer located at the second region includes at least one inorganic layer pattern extending in the second direction and covering an edge of the power supply signal line extending in the first direction.

For example, the at least one inorganic layer pattern includes a plurality of inorganic layer patterns, the number of the strip-shaped barriers is at least one, and the strip-shaped barriers and the plurality of inorganic layer patterns are alternately arranged in the first direction.

For example, an edge of the strip-shaped barrier covers at least a portion of an edge of the inorganic layer pattern.

For example, the base substrate includes a third region surrounding a portion of the display region; an orthographic projection of an edge of a portion of the power supply signal line located at the third region on the base substrate is completely within the orthographic projection of the at least one ring of barrier on the base substrate.

For example, in a direction perpendicular to the base substrate, the portion of the power supply signal line located at the third region does not overlap with the inorganic layer.

For example, the power supply signal line includes a first power supply signal line and a second power supply signal line, the first power supply signal line includes portions located at the first region and the second region, and only the second power supply signal line is provided in the third region.

Another embodiment of the present disclosure provides a display device, which includes any display substrate as mentioned above.

### BRIEF DESCRIPTION OF THE DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1 is a schematic partial planar structure diagram of a display substrate according to an example of the present disclosure.

FIG. 2 is a partial structure diagram of a first region and a second sub-region in a second region in the display substrate shown in FIG. 1.

FIG. 3 is an enlarged partial diagram of the second region shown in FIG. 1.

FIG. 4 is an enlarged partial diagram of a first sub-region shown in FIG. 3.

FIG. 5 is a schematic partial cross-sectional structure diagram of a second sub-region in a second region provided according to an example of an embodiment of the present disclosure.

FIG. 6 is a schematic partial cross-sectional structure diagram of a second region in a general display substrate.

FIG. 7 is a schematic partial cross-sectional structure diagram of a second region provided according to another example of an embodiment of the present disclosure.

FIG. 8 is a partial structure diagram of a first region and a first sub-region in a second region in the display substrate shown in FIG. 1.

FIG. 9 is an enlarged partial diagram of a first sub-region shown in FIG. 3.

FIG. 10 is schematic partial cross-sectional structure diagram of a first sub-region in a second region provided according to an example of an embodiment of the present disclosure.

FIG. 11 is a schematic partial cross-sectional structure diagram of a first sub-region in a second region in a general display substrate.

FIG. 12 is a schematic partial planar structure diagram of an area of a general display substrate having a barrier disposed within a second region.

FIG. 13 is a schematic partial planar structure diagram of an area having a barrier disposed within a second region provided according to an embodiment of the present disclosure.

FIG. 14 is a schematic partial cross-sectional structure diagram taken along line CC′ of FIG. 13.

FIG. 15 is a schematic block diagram of a display device provided according to another embodiment of the present disclosure.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects.

The features “parallel”, “perpendicular” and “same” used in the embodiments of the present disclosure all include features such as “parallel”, “perpendicular” and “same” in the strict sense, and the cases having certain errors, such as “approximately parallel”, “approximately perpendicular”, “approximately the same” or the like, taking into account measurements and errors associated with the measurement of a particular quantity (e.g., limitations of the measurement system), and indicate being within an acceptable range of deviation for a particular value as determined by one of ordinary skill in the art. For example, “approximately” may indicate being within one or more standard deviations, or within 10% or 5% of the stated value. In the case that the quantity of a component is not specifically indicated below in the embodiments of the present disclosure, it means that the component may be one or more, or may be understood as at least one. “At least one” means one or more, and “plurality” means at least two. The “same layer arrangement” mentioned in the present disclosure refers to the structure formed by two (or more) structures formed by the same deposition process and patterned by the same patterning process, and their materials may be the same or different.

The present disclosure provides a display substrate and a display device. The display substrate includes a base substrate, and a conductive structure and an inorganic layer located on the base substrate. The base substrate includes a first region and a second region. The conductive structure is located in the first region and the second region on the base substrate. The inorganic layer is located on a side of the conductive structure away from the substrate and is located in the first region and the second region, the first region includes a display region, and the second region includes a portion of a non-display region. The display region includes a plurality of sub-pixels and a definition structure. At least some of the sub-pixels each include a light-emitting functional layer, the light-emitting functional layer includes a plurality of film layers. The definition structure includes a portion of the inorganic layer located in the display region, the definition structure is located between the light-emitting functional layer and the base substrate. A portion of the definition structure located between adjacent sub-pixels is configured for isolating at least one layer of the light-emitting functional layer. In the second region, the inorganic layer includes a sub-portion that exposes at least a portion of the conductive structure, and/or the inorganic layer includes a sub-portion in contact with the conductive structure. In the display substrate provided by the present disclosure, it is advantageous to save the mask process and reduce the production cost by providing the inorganic layer to include, a sub-portion exposing the conductive structure in the second region and/or a sub-portion in contact with the conductive structure in addition to the portion including the definition structure.

Hereinafter, the display substrate and the display device provided by embodiments of the present disclosure will be described with reference to the accompanying drawings.

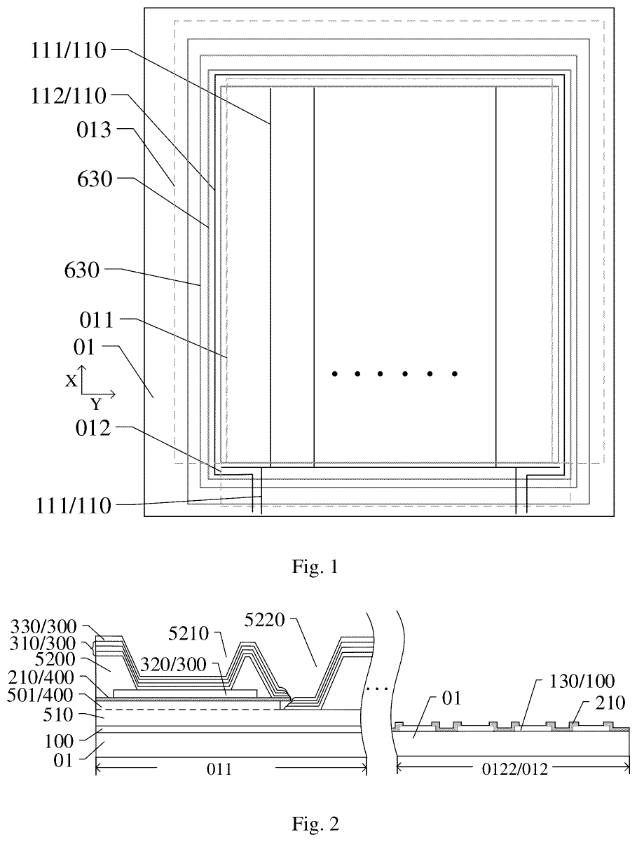

FIG. 1 is a partial planar structure diagram of a display substrate according to an example of the present disclosure. FIG. 2 is a partial structure diagram of a first region and a second sub-region in a second region in the display substrate shown in FIG. 1.

As shown in FIGS. 1 and 2, the display substrate includes a base substrate 01, and a conductive structure 100 and an inorganic layer 210 located on the base substrate 01. The base substrate 01 includes a first region 011 and a second region 012. The conductive structure 100 is located in the first region 011 and the second region 012 on the base substrate 01. The inorganic layer 210 is located on a side of the conductive structure 100 away from the base substrate 01 and is located in the first region 011 and the second region 012. The first region 011 includes a display region, and the second region 012 includes a portion of a non-display region. For example, the display region is an area for displaying an image, and the non-display region is an area for not displaying an image. For example, the second region 012 is located on a side of the first region 011 in an X direction. For example, the second region 012 is located on a lower side of the first region 011 in the direction indicated by an arrow in the X-direction shown in FIG. 1. For example, the conductive structure 100 may be a metal structure.

As shown in FIGS. 1 and 2, the display region includes a plurality of sub-pixels 300 and a definition structure 400. At least some of the sub-pixels 300 each include a light-emitting functional layer 310, the light-emitting functional layer 310 includes a plurality of film layers. The definition structure 400 includes a portion of the inorganic layer 210 located in the display region, the definition structure 400 is located between the light-emitting functional layer 310 and the base substrate 01, and a portion of the definition structure 400 located between adjacent sub-pixels 300 is configured for isolating at least one layer of the light-emitting functional layer 310. In the second region 012, the inorganic layer 210 includes a sub-portion that exposes at least a portion of the conductive structure 100. For example, the inorganic layer 210 covers an edge of the surface of the conductive structure 100 on a side away from the base substrate 01 and a sidewall of the conductive structure 100. For example, the inorganic layer 210 exposes an intermediate portion of the surface of the side of the conductive structure 100 away from the base substrate 01.

In the display substrate provided by the present disclosure, it is advantageous to save the mask process and reduce the production cost by providing the inorganic layer to include a portion, exposing the conductive structure, in the second region in addition to the portion including the definition structure.

In some examples, as shown in FIG. 2, each of at least some of the sub-pixels 300 further includes a first electrode 320 and a second electrode 330 located on both sides of the light-emitting functional layer 310, the first electrode 320 is located between the light-emitting functional layer 310 and the base substrate 01. For example, the plurality of sub-pixels 300 includes sub-pixels that emit different colors of light, such as red sub-pixels that emit red light, green sub-pixels that emit green light, and blue sub-pixels that emit blue light.

For example, as shown in FIG. 2, each sub-pixel 300 located in the display region includes a light-emitting element. For example, the light-emitting functional layer 310 includes a charge generation layer. For example, the light-emitting functional layer 310 may be a light-emitting functional layer 310 included in an organic light-emitting element, and the light-emitting functional layer 310 includes an organic light-emitting layer.

For example, as shown in FIG. 2, the light-emitting functional layer 310 may include a first light-emitting layer (EML), a charge generation layer (CGL), and a second light-emitting layer (EML) arranged in a stack, the charge generation layer is located between the first light-emitting layer and the second light-emitting layer. The charge generation layer has strong electrical conductivity, so that the light-emitting functional layer 310 has advantages of long lifetime, low power consumption, and high brightness. For example, the sub-pixel 300 may increase the luminance of light emission nearly twice by providing the charge generation layer in the light-emitting functional layer 310 with respect to the light-emitting functional layer 310 without providing the charge generation layer.

For example, the light-emitting elements of the same sub-pixel 300 may be tandem light-emitting elements such as Tandem OLED.

For example, the charge generation layer may include an N-type charge generation layer and a P-type charge generation layer.

For example, in each sub-pixel 300, the light-emitting functional layer 310 may further include a hole injection layer (HIL), a hole transfer layer (HTL), an electron transfer layer (ETL), and an electron injection layer (EIL).

For example, the hole injection layer, the hole transfer layer, the electron transfer layer, the electron injection layer, and the charge generation layer are each a common film layer of the plurality of sub-pixels 300, and may be referred to as a common layer. For example, the common layer and the second electrode 330 may be a film layer formed using an open mask.

For example, the first electrode 320 may be an anode and the second electrode 330 may be a cathode. For example, the cathode can be formed of a material having high conductivity and low work function. For example, the cathode can be made of a metal material. For example, the anode can be formed of a transparent conductive material having a high work function.

For example, as shown in FIG. 2, the orthographic projection of the second electrode 330 in at least a portion of the sub-pixels 300 on the base substrate 01 is a whole surface structure. For example, the second electrode 330 may be a common electrode shared by the plurality of sub-pixels 300.

For example, as shown in FIG. 2, the definition structure 400 may disconnect the charge generation layer to prevent cross-talk between adjacently disposed different color sub-pixels 300. For example, all film layers in the light-emitting functional layer 310 between the charge generation layer and the base substrate 01 may be disconnected at the edges of the definition structure 400. For example, all of the film layers in the light-emitting functional layer 310 may be disconnected at the edges of the definition structure 400. For example, the second electrode 330 may be disconnected at the edges of the definition structure 400 or may be continuously disposed.

In some examples, as shown in FIG. 2, the display substrate further includes an organic layer 510 located between the film layer where the inorganic layer 210 is positioned and the base substrate 01. The definition structure 400 further includes a plurality of protrusions 501 in the organic layer 510 in contact with the surface of the inorganic layer 210, at least a portion of the edges of the protrusions 501 is retracted inward respect to the edges of the inorganic layer 210 in the definition structure 400. For example, the organic layer 510 includes a plurality of protrusions 501. The plurality of protrusions 501 is arranged in one-to-one correspondence with the plurality of sub-pixels 300. The orthographic projection of the light-emitting region of the sub-pixel 300 on the base substrate 01 is located within the orthographic projection of the protrusion 501 on the base substrate 01.

For example, as shown in FIG. 2, the definition structure 400 includes the inorganic layer 210 and protrusions 501 of the organic layer 510. For example, the orthographic projection of the first electrode 320 of the sub-pixel 300 on the base substrate 01 is completely within the orthographic projection of the definition structure 400 on the base substrate 01. For example, the orthographic projection of the protrusion 501 on the base substrate 01 is completely within the orthographic projection of the inorganic layer 210 on the base substrate 01. For example, the thickness of the organic layer 510 may be 2 microns. For example, the portion of the organic layer 510 located in the display region may be a planarization layer (PLN) closest to the first electrode 320 of the sub-pixel 300. For example, the material of the inorganic layer 210 may include silicon nitride, silicon oxide, or silicon oxynitride.

For example, the material of the organic layer 510 may include polyimide or the like.

In some examples, as shown in FIG. 2, the display substrate further includes a pixel definition pattern 5200, the pixel definition pattern 5200 includes a plurality of first openings 5210 and a plurality of second openings 5220. One sub-pixel 300 corresponds to at least one first opening 5210, at least a portion of the light-emitting functional layer 310 of the sub-pixel 300 is located in the first opening 5210 corresponding to the sub-pixel 300, the first opening 5210 is configured for exposing the first electrode 320, and the second opening 5220 is configured for exposing an edge of the definition structure 400.

For example, as shown in FIG. 2, one sub-pixel 300 corresponds to one first opening 5210. The light-emitting functional layer 310 located in the first opening 5210 realizes light emission by contacting the first electrode 320 and the second electrode 330. For example, the first opening 5210 is configured to define a light-emitting region of the sub-pixel 300. For example, the edge of the definition structure 400 exposed by the second opening 5220 is configured to isolate at least one layer of the light-emitting functional layer 310. For example, the pixel definition pattern 5200 includes a pixel definition portion surrounding the first opening 5210 and the second opening 5220. The light-emitting functional layer 310 may include a portion located within the first opening 5210 and a portion located on the pixel definition portion.

FIG. 2 does not show other film layers between the conductive structure 100 and the base substrate 01. For example, at least one metal layer and a multi-layer insulating layer are further provided between the conductive structure 100 and the base substrate 01. For example, at least one metal layer includes structures such as a gate electrode of a thin film transistor of a pixel circuit, and a gate line electrically connected to the gate electrode. For example, the multi-layer insulating layer includes film layers such as a gate insulating layer, a buffer layer and an interlayer insulating layer. FIG. 2 omits a structure between the pixel definition pattern 5200 and the contact pad 130.

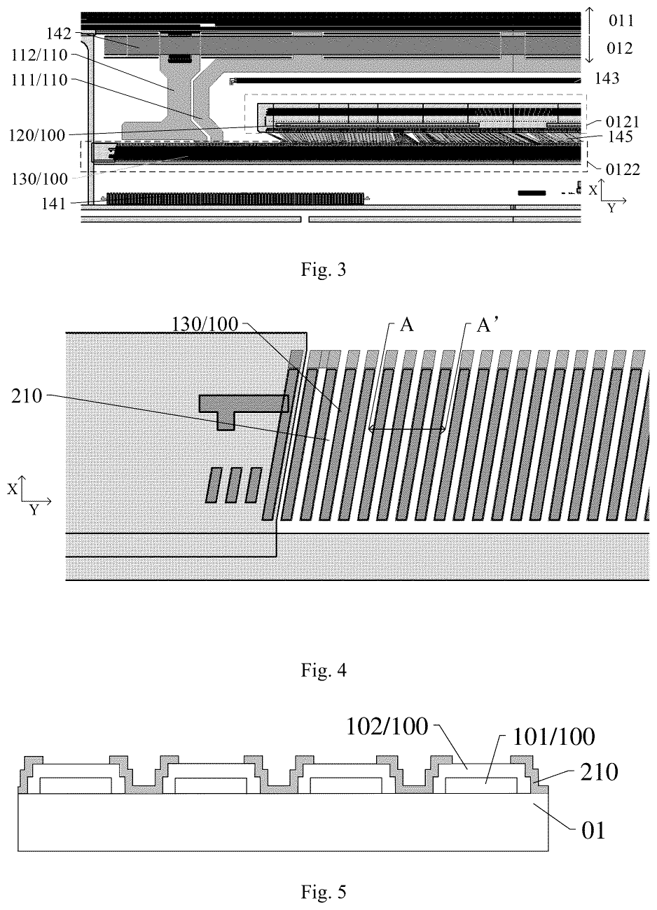

FIG. 3 is an enlarged partial diagram of the second region shown in FIG. 1. FIG. 4 is an enlarged partial diagram of the first sub-region shown in FIG. 3. The schematic partial cross-sectional structural diagram of the second region 012 in FIG. 2 may be a schematic partial cross-sectional structural diagram taken along the line AA′ shown in FIG. 4.

In some examples, as shown in FIGS. 2-4, the second region 012 includes a first sub-region 0121 and a second sub-region 0122 in which the inorganic layer 210 covers an edge of the conductive structure 100. For example, the second region 012 includes at least a portion of a bonding region, and the second sub-region 0122 is located in the bonding region.

In some examples, as shown in FIG. 3, the first sub-region 0121 is located between the second sub-region 0122 and the first region 011. For example, as shown in FIG. 3, the second region 012 further includes a pin 141 and a pin 143 required for the test stage, and a trace 142 located in the bending region and connected to a signal line (e.g., a data line, etc.) located in the display region.

In some examples, as shown in FIG. 4, the portion of the conductive structure 100 located in the second sub-region 0122 includes contact pads 130 configured for electrically connecting with pins of a circuit board. For example, the contact pad 130 is a structure for bonding with a pin of the circuit board. For example, the second sub-region 0122 may be a lower contact pad region. For example, the circuit board may be a flexible circuit board (FPC) and the second sub-region 0122 may be a FOP (FPC on panel) region. For example, the conductive structure 100 includes a plurality of contact pads 130 arranged in the Y direction, the inorganic layer 210 is disposed between adjacent contact pads 130, and the inorganic layer 210 wraps around one ring of the edge of each contact pad 130. A portion of the contact pad 130 not covered by the inorganic layer 210 is used for bonding with a pin of the circuit board.

For example, FIG. 2 schematically illustrates that the conductive structure 100 includes a one-layer structure, but is not limited thereto. The conductive structure 100 may include a multi-layer structure, and one organic layer, or one organic layer and one inorganic layer may be disposed between two adjacent layers in the multi-layer structure of the first region 011. For example, the boundaries of different layers of conductive structure 100 may be the same or different.

For example, as shown in FIG. 2, the inorganic layer 210 may have a thickness of 20-100 nanometers, or 30-50 nanometers, or 40-80 nanometers, or 60-90 nanometers.

For example, as shown in FIG. 2, in the second region 012, no other inorganic layer is provided between the inorganic layer 210 and the conductive structure 100.

For example, in the second region 012, no other organic layer is provided between the inorganic layer 210 and the conductive structure 100.

FIG. 5 is a schematic partial cross-sectional structure diagram of a second sub-region in a second region provided according to an example of an embodiment of the present disclosure. The structure shown in FIG. 5 differs from the structure shown in FIG. 2 in that the conductive structure 100 includes different structural layers. The schematic partial cross-sectional structural diagram of the second region 012 in FIG. 5 may be a schematic partial cross-sectional structural diagram taken along the line AA′ shown in FIG. 4.

For example, as shown in FIG. 5, the conductive structure 100 includes a multi-layer sub-conductive structure, such as a two-layer sub-conductive structure, including a first sub-conductive structure 101 and a second sub-conductive structure 102, the first sub-conductive structure 101 is located between the second sub-conductive structure 102 and the base substrate 01. For example, the boundary of the second sub-conductive structure 102 may be larger than the boundary of the first sub-conductive structure 101, but is not limited thereto. The boundary of the second sub-conductive structure 102 may be flush with the boundary of the first sub-conductive structure 101. For example, the first sub-conductive structure 101 may be in contact with the second sub-conductive structure 102. For example, the materials of the first sub-conductive structure 101 and the second sub-conductive structure 102 may be the same. For example, each layer of the sub-conductive structure 100 may include multiple metal layers, such as titanium/aluminum/titanium in a stacked arrangement. For example, the contact pad 130 may include a titanium/aluminum/titanium metal layer.

For example, as shown in FIG. 5, the inorganic layer 210 covers the surface of the second sub-conductive structure 102 away from the base substrate 01. For example, the inorganic layer 210 covers the side surfaces of the second sub-conductive structure 102. However, the inorganic layer covers the side surface of the first sub-conductive structure and the side surface of the second sub-conductive structure when the boundary of the second sub-conductive structure is flush with the boundary of the first sub-conductive structure.

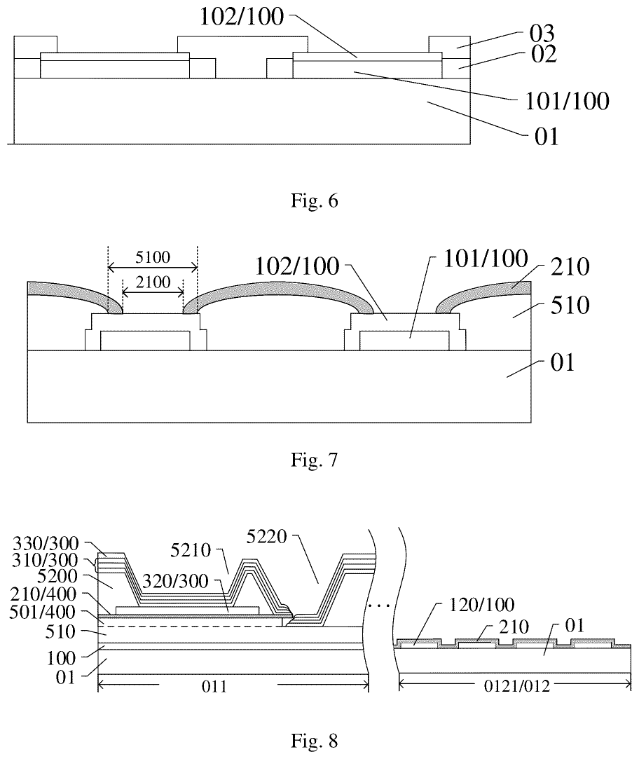

FIG. 6 is a schematic partial cross-sectional diagram structure of a second region in a general display substrate. As shown in FIG. 6, in a general display substrate, a first sub-conductive structure 101 is in direct contact with a second sub-conductive structure 102, and a side of the second sub-conductive structure 102 away from the base substrate 01 is provided with a planarization layer 03. The planarization layer 03 shown in FIG. 6 may be a portion of the organic layer 510 shown in FIG. 2 located in the second region 012.

With respect to the case where the passivation layer and the planarization layer are used to cover the edge of the conductive structure 100 in the general display substrate as shown in FIG. 6, the present disclosure provides a display substrate in which the inorganic layer 210 is used in place of the passivation layer and the inorganic layer 210 is used in place of the planarization layer portion of the organic layer 510 in the second region 012, which is advantageous in improving the yield of the FPC bonding process while reducing the mask process for patterning the passivation layer to reduce the production cost. It is beneficial to solve the problems of the second region 012, such as a dark spot caused by the influence of the residual metal on the subsequent wet etching of the anode due to the larger thickness of the originally provided planarization layer, and FPC bonding peeling caused by the poor adhesion between the originally provided passivation layer and the planarization layer.

In some examples, as shown in FIGS. 2 and 5, in a direction perpendicular to the base substrate 01, a portion of the conductive structure 100 located in at least a portion of the second region 012 does not overlap with the organic layer 510. For example, the edges of the conductive structure 100 are not covered by the organic layer 510. For example, the pad bending zone is not provided with an organic layer.

In some examples, as shown in FIGS. 2 and 5, in a direction perpendicular to the base substrate 01, at least a portion of the organic layer 510 located within the second region 012 is removed. For example, the second region 012 is not provided with the organic layer 510.

FIG. 7 is a schematic partial cross-sectional structure diagram of a second region provided according to another example of an embodiment of the present disclosure. The structure shown in FIG. 7 differs from the structure shown in FIG. 5 in that the portion of the organic layer 510 located in the second region 012 is located between the inorganic layer 210 and the base substrate 01. The schematic partial cross-sectional structural diagram of the second region 012 in FIG. 7 may be a schematic partial cross-sectional structural diagram taken along the line AA′ shown in FIG. 4.

In research, the inventors of the present application found that in the patterning process of the inorganic layer 210 provided in the definition structure 400 for isolating the light-emitting functional layer 310 of the adjacent sub-pixels 300 with different colors provided in the display region, the portion of the inorganic layer 210 located in the second region 012 needs to be completely etched away, which easily causes the organic layer 510 at the edge of the contact pad 130 in the second region 012 and the contact pad 130 itself are easily over-etched, resulting in that the titanium in the side of the contact pad 130 furthest away from the base substrate 01 is easily etched, and even the intermediate layer of aluminum included in the contact pad 130 may be corroded, thereby affecting the quality of the display substrate when used for display.

In some examples, as shown in FIG. 7, in the second region 012, the organic layer 510 covers an edge of the conductive structure 100, and the inorganic layer 210 completely covers an edge of the organic layer 510 and exposes at least a portion of the conductive structure 100. For example, the organic layer 510 includes a via hole 5100 for exposing the conductive structure 100, and the boundary of the organic layer 510 around the via hole is completely covered by the inorganic layer 210 such that the via hole 2100 formed in the inorganic layer 210 and the via hole 5100 in the organic layer 510 form a socket hole structure. For example, the size of the via hole 2100 in the inorganic layer 210 is less than the size of the via hole 5100 in the organic layer 510. For example, the orthographic projection of the via hole 2100 in the inorganic layer 210 on the base substrate 01 is completely within the orthographic projection of the via hole 5100 in the organic layer 510 on the base substrate 01.

In the display substrate provided by the present disclosure, the inorganic layer covering the organic layer in the second region is patterned while forming the inorganic layer included in the definition structure in the display region, so as to replace the passivation layer between the organic layer and the base substrate in general display substrates and save one-step masking process, and at the same time, the edge of the organic layer and the edge of the contact pad are protected by the inorganic layer, so as to prevent the contact pad and the organic layer covering the contact pad in the second region from being affected in the process of patterning the definition structure in the display region.

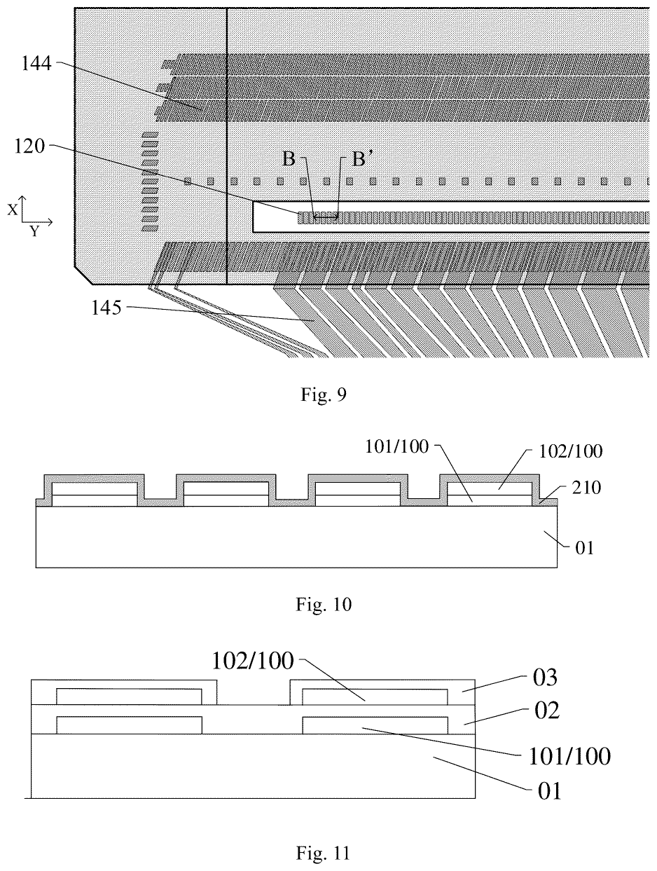

FIG. 8 is a partial structure diagram of a first region and a first sub-region in a second region in the display substrate shown in FIG. 1. FIG. 9 is an enlarged partial diagram of the first sub-region shown in FIG. 3. The structure of the first sub-region 0121 shown in FIG. 8 may be a schematic partial cross-sectional structure taken along the line BB′ shown in FIG. 9.

As shown in FIGS. 8 and 9, in the second region 012, the inorganic layer 210 includes a sub-portion in contact with the conductive structure 100. For example, the inorganic layer 210 completely covers the surface of the conductive structure 100.

In some examples, as shown in FIGS. 8 and 9, in the first sub-region 0121, the inorganic layer 210 covers the conductive structure 100 and is in contact with a surface of the conductive structure 100. For example, the first sub-region 0121 is located in the bonding region. For example, the first sub-region 0121 may be a circuit board bonding region, such as an IC bonding region.

In some examples, as shown in FIGS. 8 and 9, the portion of the conductive structure 100 located in the first sub-region 0121 includes an AT (Array Test) test circuit cell, such as including a test pad 120 (AT Pad). For example, the conductive structure 100 includes a plurality of test pads 120 arranged in the Y-direction, the surface of each test pad 120 away from the base substrate 01 and the side surface are covered by the inorganic layer 210. For example, spaces between adjacent test pads 120 are covered by the inorganic layer 210. For example, after the fabrication of a display substrate, such as an array substrate, an Array Test (AT) device loads a signal required for driving the array substrate from an AT Pad, converts a pressure difference between defective and normal pixels into a light intensity difference using optical and electrical simulation display, and then outputs an image signal by photoelectric conversion and searches for a defect. After the array substrate has been tested, the AT Pad described above needs to be covered to avoid adverse effects in subsequent processes.

For example, as shown in FIG. 9, the second region also includes pins 144 that are electrically connected to a circuit board (e.g., a COP) and connection traces 145 that connect the pins in the first sub-region and second sub-region.

For example, FIG. 8 schematically illustrates conductive structure 100 as a one-layer structure, which, however, is not limited thereto.

FIG. 10 is partial schematic cross-sectional diagram of a structure of a first sub-region in a second region provided according to an example of an embodiment of the present disclosure. The structure shown in FIG. 10 differs from the structure shown in FIG. 8 in that the conductive structure 100 includes different structural layers. The schematic partial cross-sectional structural diagram of the second region 012 in FIG. 10 may be a schematic partial cross-sectional structural diagram taken along the line BB′ shown in FIG. 9.

For example, as shown in FIG. 10, the conductive structure 100 includes a multi-layer sub-conductive structure, such as a two-layer sub-conductive structure, including a first sub-conductive structure 101 and a second sub-conductive structure 102, the first sub-conductive structure 101 is located between the second sub-conductive structure 102 and the base substrate 01. For example, the boundary of the second sub-conductive structure 102 may be flush with the boundary of the first sub-conductive structure 101. But not limited thereto, the boundary of the second sub-conductive structure 102 may be larger than the boundary of the first sub-conductive structure 101. For example, the first sub-conductive structure 101 may be in contact with the second sub-conductive structure 102. For example, the material of the first sub-conductive structure 101 and the second sub-conductive structure 102 may be the same. For example, each layer of the sub-conductive structure 100 may include multiple metal layers, such as titanium/aluminum/titanium in a stacked arrangement. For example, the test pad 120 may include a titanium/aluminum/titanium metal layer.

For example, as shown in FIG. 10, the inorganic layer 210 covers the surface of the second sub-conductive structure 102 away from the base substrate 01. For example, the inorganic layer 210 covers the side surfaces of the second sub-conductive structure 102. For example, the inorganic layer 210 covers a side surface of the first sub-conductive structure 101 and a side surface of the second sub-conductive structure 102.

FIG. 11 is a schematic partial cross-sectional structure diagram of a first sub-region in a second region in a general display substrate. As shown in FIG. 11, in a general display substrate, a passivation layer 02 is provided between a first sub-conductive structure 101 and a second sub-conductive structure 102, and a planarization layer 03 is provided on a side of the second sub-conductive structure 102 away from a base substrate 01. The planarization layer 03 shown in FIG. 11 may be a portion of the organic layer 510 shown in FIG. 8 located in the second region 012, e.g., the portion of the planarization layer covering the second sub-conductive structure 102 may be a thinned film layer.

With respect to a structure in which a passivation layer is used in combination with an organic layer to respectively cover a test pad in the general display substrate shown in FIG. 11, the present disclosure provides the display substrate in which the inorganic layer 210 is used to simultaneously replace the passivation layer and the organic layer on the test pad 120, so as to reduce the production cost of a mask process while protecting the test pad 120 from adverse effects in subsequent processes.

For example, as shown in FIGS. 8 and 10, no organic layer 510 is disposed in the first sub-region 0121. By not providing the organic layer 510 in the first sub-region 0121, the yield of IC bonding may be improved, and the manufacturing cost and production efficiency of the backplate circuit can be greatly reduced to avoid such adverse problems as dark spots caused by subsequent processes at this position.

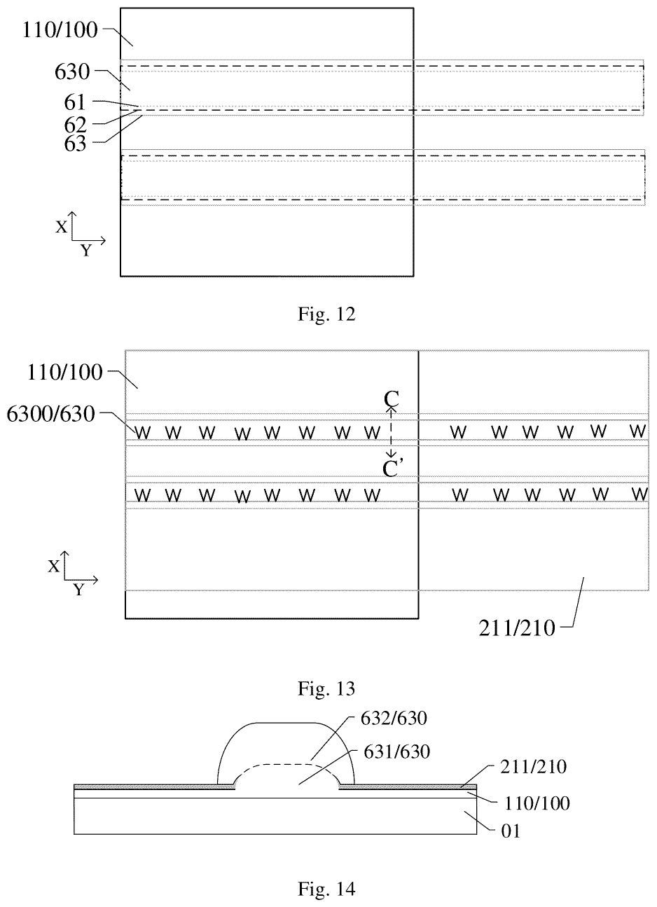

FIG. 12 is a schematic partial planar structure diagram of an area of a general display substrate having a barrier disposed within a second region.

In research, the inventors of the present application found that, as shown in FIG. 12, the conductive structure 100 in the second region 012 in the general display substrate includes a power supply signal line 110, a side of the power supply signal line 110 away from the base substrate 01 is provided with a barrier 630, and each layer of the organic layer 510 on the power supply signal line 110 at a position other than the position covered by the barrier 630 is removed. For example, a side of the power supply signal line 110 away from the base substrate 01 is provided with three layers of the organic layer 510. For example, an organic layer 61, an organic layer 62 and an organic layer 63 are successively stacked and arranged perpendicular to the base substrate, the organic layer 61 is located between the organic layer 62 and the base substrate. The three organic layers are provided in the barrier 630, and the power supply signal line 110 at a position other than the barrier 630 is exposed by the gap outside the three organic layers. Thus, in the process of patterning the first electrode for forming the sub-pixel, the position where the power supply signal line 110 is exposed may be etched to generate an undercut structure, resulting in a crack of an encapsulation layer which is then formed on the etched surface of the power supply signal line 110, affecting the encapsulation effect, thereby forming a water vapor invasion path and generating a growth-type GDS defect, affecting the picture quality displayed in the display region.

At present, the main solution of the defect is to form a passivation layer (such as the passivation layer 02 shown in FIGS. 6 and 11) on the side of the power supply signal line 110 away from the base substrate after patterning the power supply signal line 110 so as to protect the power supply signal line 110 from the undercut and GDS defects when patterning to form the first electrode of the sub-pixel.

FIG. 13 is a partial cross-sectional schematic structure of a region having a barrier disposed within a second region provided according to an embodiment of the present disclosure. FIG. 14 is a partial cross-sectional view taken along line CC′ of FIG. 13.

In some examples, as shown in FIGS. 1, 13, and 14, the portion of the conductive structure 100 located in the second region 012 includes a power supply signal line 110, and the inorganic layer 210 is in contact with part of a surface of the power supply signal line 110. For example, the power supply signal line 110 may be a signal line that transmits at least one of a VDD power signal and a VSS power signal.

In some examples, as shown in FIGS. 1, 13, and 14, the display substrate further includes: at least one ring of the barrier 630 surrounds the display region, and at least a portion of the film layer of the barrier 630 is located on a side of the conductive structure 100 away from the base substrate 01. The orthographic projection of the power supply signal line 110 on the base substrate 01 overlaps with the orthographic projection of the at least one ring of the barrier 630 on the base substrate 01. The portion of the power supply signal line 110 located at the second region 012 extends in a first direction, the portion of the at least one ring of the barrier 630 located at the second region 012 includes a strip-shaped barrier 6300 extending in a second direction, the at least portion of the inorganic layer 210 located at the second region 012 extends in the second direction, the first direction intersects the second direction. For example, the first direction may be the X direction shown in the figure and the second direction may be the Y direction shown in the figure. For example, the angle between the first direction and the second direction may be 80-100 degrees. For example, the first direction is perpendicular to the second direction. The embodiments of the present disclosure are not limited thereto, and the first direction and the second direction may be interchanged.

In some examples, as shown in FIGS. 1, 13, and 14, at least a portion of the inorganic layer 210 in the second region 012 includes at least one inorganic layer pattern 211 extending in the second direction and covering an edge of the power supply signal line 110 extending in the first direction. For example, the inorganic layer pattern 211 may be a strip-shaped film layer.

The present disclosure provides the display substrate with the inorganic layer at the portion of the display region for forming the definition structure to isolate at least one layer of the light-emitting functional layer in adjacent sub-pixels of different colors, so as to achieve the purpose of reducing crosstalk, and at the same time, the inorganic layer located at a portion of a non-display region covers the edge of the power supply signal line exposed by a barrier, which can enhance the strict reliability verification condition of the non-display area and avoid the related growth type dark spot (GDS) problem. With respect to a general display substrate provided with a passivation layer (such as the passivation layer 02 shown in FIGS. 6 and 11) on the side of the conductive structure away from the substrate, the present disclosure provides the display substrate, in which the inorganic layer replaces the above-mentioned passivation layer. Thus, on the basis of compatibility with the film layer of the definition structure in the display region, the inorganic layer protects the power supply signal line exposed by the barrier in the second region while saving the mask process for forming the above-mentioned passivation layer, so as to save production costs while improving the production capacity of a backboard circuit.

In some examples, as shown in FIGS. 1, 13, and 14, the at least one inorganic layer pattern 211 includes a plurality of inorganic layer patterns 211, the number of strip-shaped barriers 6300 is at least one, and the strip-shaped barriers 6300 and the plurality of inorganic layer patterns 211 are alternately arranged in the first direction. For example, the number of the strip-shaped barriers 6300 is two. The number of the inorganic layer patterns 211 is three, the inorganic layer patterns 211 and the strip-shaped barriers 6300 are alternately arranged in the first direction, and the inorganic layer patterns 211 are located on both sides of the strip-shaped barriers 6300.

In some examples, as shown in FIG. 1, FIG. 13, and FIG. 14, an edge of the strip-shaped barrier 630 covers at least a portion of an edge of the inorganic layer pattern 211. For example, the edges of the inorganic layer pattern 211 located on both sides of the strip-shaped barrier 6300 and close to the strip-shaped barrier 630 extend into the strip-shaped barrier 6300 so as to prevent a portion of the conductive structure 100 from being exposed when the strip-shaped barrier 6300 and the inorganic layer pattern 211 are distributed in a misaligned manner due to process reasons. For example, the inorganic layer pattern 211 covers the conductive structure 100 exposed by the strip-shaped barrier 6300.

For example, as shown in FIG. 14, the barrier 630 may include a first film layer 631 and a second film layer 632 arranged in a stack, the second film layer 632 is located on a side of the first film layer 631 away from the base substrate 01. For example, a portion of the organic layer 510 located in the second region 012 serves as the first film layer 631 of the barrier 630, and a portion of the film layer where the pixel definition portion in the pixel definition pattern 5200 is located in the second region 012 serves as the second film layer 632 of the barrier 630. FIG. 14 schematically illustrates that the first film layer includes one film layer, but is not limited thereto, and that the first film layer may include at least two film layers, such as two planarization layers.

For example, as shown in FIGS. 13 and 14, in a direction perpendicular to the base substrate 01, a portion where the inorganic layer pattern 211 overlaps with the barrier 630 is located between the first film layer 631 and the second film layer 632. For example, the first film layer 631 and the second film layer 632 may be made of the same material, and in a position other than the position where the inorganic layer 210 is provided between the first film layer 631 and the second film layer 632 of the barrier 630, there may be no obvious boundary line between the first film layer 631 and the second film layer 632.

For example, as shown in FIG. 13 and FIG. 14, the size, of the portion where the inorganic layer pattern 211 overlaps with the strip-shaped barrier 6300 in the direction perpendicular to the base substrate 01, in the first direction is 10-40 microns, or 15-20 microns, or 12-18 microns.

In some examples, as shown in FIG. 1, the base substrate 01 includes a third region 013 surrounding a portion of the display region, the orthographic projection of the edge of the portion, in the third region 013, of the power supply signal line 110 on the base substrate 01 is completely within the orthographic projection of the at least one ring of the barrier 630 on the base substrate 01. For example, the first region 011 is a display region, and the third region 013 and the second region 012 constitute a ring of non-display regions around the display region. For example, the second region 012 is located at the lower side of the display region, and the fourth region 014 is located at the upper side, the left side, and the right side of the display region. For example, a ring of the barrier 630 is distributed in a ring of the non-display region including the fourth region 014 and the second region 012. The barrier 630 located at the fourth region 014 completely covers the edge of the power supply signal line 110. The barrier 630 located at the second region 012 intersects with the power supply signal line and exposes a portion of the edge of the power supply signal line 110, and the edge of the power supply signal line 110 which is exposed is covered with the inorganic layer 210.

In some examples, as shown in FIGS. 1, 13, and 14, in a direction perpendicular to the base substrate 01, the portion of the power supply signal line 110 located in the third region 013 does not overlap with the inorganic layer 210. For example, the inorganic layer 210 is not disposed in the third region 013. For example, the inorganic layer 210 is disposed only on the lower side where the second region 012 is located (e.g., the lower pad region) in a ring of non-display regions outside the display region. For example, the edge of the power supply signal line 110 includes a portion covered only by the inorganic layer 210, a portion covered only by the barrier 630, and a portion covered both by the inorganic layer 210 and the strip-shaped barrier 630.

In some examples, as shown in FIGS. 1 and 3, the power supply signal line 110 includes a first power supply signal line 111 and a second power supply signal line 112. The first power supply signal line 111 includes portions located in the first region 011 and the second region 012, and only the second power supply signal line 112 is provided in the third region 013. For example, the second power supply signal line 112 may be a VSS power supply signal line that may be connected to a voltage source to output a constant voltage signal, such as a negative voltage signal. For example, the second power supply signal line 112 may also be grounded. For example, the first power supply signal line 111 may be a VDD power supply signal line that may be connected to a voltage source to output a constant voltage signal, such as a positive voltage signal. For example, the first power supply signal line 111 further includes a portion located at a display region to be electrically connected with a pixel circuit included in the sub-pixel 300 to provide a power supply signal. For example, the second power supply signal line 112 is located at a non-display region and disposed around the display region. The second power supply signal line 112 may include a portion located at the display region to be electrically connected to the second electrode 330 included in the sub-pixel 300. For example, the second power supply signal line 112 is located on both sides of the first power supply signal line 111 in the second direction. For example, the conductive structure 100 shown in FIG. 13 may be the second power supply signal line 112, but is not limited thereto, and may be the first power supply signal line 111.

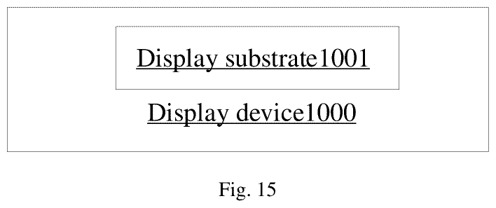

FIG. 15 is a schematic block diagram of a display device provided according to another embodiment of the present disclosure. As shown in FIG. 15, the display device 1000 includes a display substrate 1001. The display substrate 1001 may be the display substrate in any one of the embodiments described above.

For example, the display device 1000 may be an organic light-emitting diode display device.

For example, the display device 1000 may further include a cover plate on the light-emitting side of the display substrate 1001.

For example, the display device 1000 may be any product or component having a display function, such as a television, a digital camera, a cell phone, a watch, a tablet computer, a notebook computer, a navigator, etc. and the present embodiment is not limited thereto.

For example, the display device 1000 may be a medium and large size intelligent hand-held display device (NB) or a touch display device (TPC), and has a wide application potential in the field of foldable products.

The following statements should be noted:
(1) The accompanying drawings involve only the structure(s) in connection with the embodiment(s) of the present disclosure, and other structure(s) can be referred to common design(s).
(2) In case of no conflict, features in one embodiment or in different embodiments can be combined.

What have been described above are only specific implementations of the present disclosure, the protection scope of the present disclosure is not limited thereto. The protection scope of the present disclosure should be based on the protection scope of the claims.

1. A display substrate, comprising:
a base substrate comprising a first region and a second region;
a conductive structure located in the first region and the second region on the base substrate; and
an inorganic layer located on a side of the conductive structure away from the base substrate and located in the first region and the second region;
wherein the first region comprises a display region, the second region comprises a portion of a non-display region, the display region comprises a plurality of sub-pixels and a definition structure; each sub-pixel in at least a portion of the sub-pixels comprises a light-emitting functional layer, the light-emitting functional layer comprises a plurality of film layers; the definition structure comprises a portion of the inorganic layer located in the display region, the definition structure is located between the light-emitting functional layer and the base substrate, and a portion of the definition structure located between adjacent sub-pixels is configured to isolate at least one layer of the light-emitting functional layer;
in the second region, the inorganic layer comprises a sub-portion exposing at least a portion of the conductive structure and/or the inorganic layer comprises a sub-portion in contact with the conductive structure.

2. The display substrate according to claim 1, further comprising:
an organic layer located between a film layer where the inorganic layer is located and the base substrate;
wherein the definition structure further comprises at least one protrusion in the organic layer in contact with a surface of the inorganic layer, at least a portion of an edge of the protrusion is retracted inward respect to an edge of the inorganic layer in the definition structure.

3. The display substrate according to claim 2, wherein, in a direction perpendicular to the base substrate, a portion of the conductive structure located in at least a portion of the second region does not overlap with the organic layer.

4. The display substrate according to claim 2, wherein, in at least a portion of the second region, the organic layer covers an edge of the conductive structure, and the inorganic layer covers an edge of the organic layer and exposes at least a portion of the conductive structure.

5. The display substrate according to claim 1, wherein the second region comprises a first sub-region in which the inorganic layer covers the conductive structure and is in contact with a surface of the conductive structure.

6. The display substrate according to claim 5, wherein a portion of the conductive structure located in the first sub-region comprises a test pad.

7. The display substrate according to claim 5, wherein the second region further comprises a second sub-region in which the inorganic layer covers an edge of the conductive structure.

8. The display substrate according to claim 7, wherein the portion of the conductive structure located in the second sub-region comprises a contact pad configured to electrically connect with a pin of a circuit board.

9. The display substrate according to claim 2, wherein, in a direction perpendicular to the base substrate, at least a portion of the organic layer located in the second region is removed.

10. The display substrate according to claim 1, wherein each sub-pixel of the at least some sub-pixels further comprises a first electrode and a second electrode located at both sides of the light-emitting functional layer, the first electrode being located between the light-emitting functional layer and the base substrate;
the display substrate further comprises a pixel definition pattern, the pixel definition pattern comprises a plurality of first openings and a plurality of second openings; one sub-pixel corresponds to at least one first opening, at least a portion of the light-emitting functional layer of the sub-pixel is located in the first opening corresponding to the sub-pixel, the first opening is configured for exposing the first electrode, and the second opening is configured for exposing an edge of the definition structure.

11. The display substrate according to claim 7, wherein the first sub-region is located between the second sub-region and the first region.

12. The display substrate according to claim 1, wherein a portion of the conductive structure located at the second region comprises a power supply signal line, and the inorganic layer is in contact with part of a surface of the power supply signal line.

13. The display substrate according to claim 12, further comprising:
at least one ring of barriers surrounding the display region, wherein at least a portion of a film layer of the barriers is located on a side of the conductive structure away from the base substrate;
wherein an orthographic projection of the power supply signal line on the base substrate overlaps with an orthographic projection of the at least one ring of barriers on the base substrate; a portion of the power supply signal line located at the second region extends in a first direction, a portion of the at least one ring of barriers located at the second region comprises a strip-shaped barrier extending in a second direction, and at least a portion of the inorganic layer located at the second region extends in the second direction, the first direction intersects with the second direction.

14. The display substrate according to claim 13, wherein at least a portion of the inorganic layer located at the second region comprises at least one inorganic layer pattern extending in the second direction and covering an edge of the power supply signal line extending in the first direction.

15. The display substrate according to claim 14, wherein the at least one inorganic layer pattern comprises a plurality of inorganic layer patterns, the number of the strip-shaped barriers is at least one, and the strip-shaped barriers and the plurality of inorganic layer patterns are alternately arranged in the first direction.

16. The display substrate according to claim 15, wherein an edge of the strip-shaped barrier covers at least a portion of an edge of the inorganic layer pattern.

17. The display substrate according to claim 13, wherein the base substrate comprises a third region surrounding a portion of the display region; an orthographic projection of an edge of a portion of the power supply signal line located at the third region on the base substrate is completely within the orthographic projection of the at least one ring of barrier on the base substrate.

18. The display substrate according to claim 17, wherein, in a direction perpendicular to the base substrate, the portion of the power supply signal line located at the third region does not overlap with the inorganic layer.

19. The display substrate according to claim 17, wherein the power supply signal line comprises a first power supply signal line and a second power supply signal line, the first power supply signal line comprises portions located at the first region and the second region, and only the second power supply signal line is provided in the third region.

20. A display device, comprising the display substrate according to claim 1.
